(19) United States
(12) Patent Application Publication
(10) Pub. No.: US 2013/0069080 A1
(43) Pub. Date: Mar. 21, 2013

(54) SEMICONDUCTOR DEVICE AND METHOD FOR MANUFACTURING SAME

(71) Applicant: Hitoshi SUGIYAMA, Kanagawa-ken (JP)

(72) Inventor: Hitoshi SUGIYAMA, Kanagawa-ken (JP)

(73) Assignee: Kabushiki Kaisha Toshiba, Tokyo (JP)

(21) Appl. No.: 13/423,506

(22) Filed: Mar. 19, 2012

(30) Foreign Application Priority Data
Sep. 21, 2011 (JP) 2011-206633

(51) Int. Cl. H01L 29/16; H01L 21/20

(52) U.S. Cl. 257/77; 438/478; 257/E29.082; 257/E21.09

(57) ABSTRACT

According to one embodiment, a semiconductor device includes a silicon carbide substrate having a first surface and a second surface on a side opposite to the first surface, a semiconductor layer having an element region and a peripheral region provided on the second surface of the silicon carbide substrate, an insulating film provided on a surface of the peripheral region of the semiconductor layer, a reinforcing substrate provided on the insulating film in the peripheral region, a first electrode provided in contact with the first surface of the silicon carbide substrate, and a second electrode provided in contact with a surface of the element region. The peripheral region is further on an edge portion side than is the element region.

### CROSS-REFERENCE TO RELATED APPLICATIONS

This application is based upon and claims the benefit of priority from the prior Japanese Patent Application No. 2011-206633, filed on Sep. 21, 2011; the entire contents of which are incorporated herein by reference.

### FIELD

Embodiments described herein relate generally to a semiconductor device and method for manufacturing same.

### BACKGROUND

In recent years, it has been proposed to use silicon carbide as a substrate of a vertical power device in which a large current flows because silicon carbide has excellent insulation breakdown voltage, high-temperature characteristics, and the like compared to silicon. In a vertical device, the resistance can be reduced by making the substrate thinner. Although there are processes for silicon carbide that can follow the processes for silicon, there are cases where independent processes are necessary for silicon carbide.

### BRIEF DESCRIPTION OF THE DRAWINGS

FIGS. 1A and 1B are schematic plane views of a semiconductor device according to the embodiment;

FIGS. 2A to FIG. 5C are schematic cross-sectional views showing a method for manufacturing a semiconductor device according to the embodiment; and

FIG. 6 is a schematic plan view showing a method for manufacturing a semiconductor device according to the embodiment.

### DETAILED DESCRIPTION

According to one embodiment, a semiconductor device includes a silicon carbide substrate having a first surface and a second surface on a side opposite to the first surface, a semiconductor layer having an element region and a peripheral region provided on the second surface of the silicon carbide substrate, an insulating film provided on a surface of the peripheral region of the semiconductor layer, a reinforcing substrate provided on the insulating film in the peripheral region, a first electrode provided in contact with the first surface of the silicon carbide substrate, and a second electrode provided in contact with a surface of the element region. The peripheral region is further on an edge portion side than is the element region.

According to another embodiment, a method for manufacturing a semiconductor device includes, bonding a reinforcing substrate to a semiconductor layer with an insulating film interposed, the semiconductor layer being provided on a second surface of a silicon carbide substrate, the silicon carbide substrate having a first surface and the second surface on a side opposite to the first surface, polishing the first surface of the silicon carbide substrate in a state of being supported by the reinforcing substrate, forming a first electrode on the polished first surface, making a through-hole in the reinforcing substrate to reach the insulating film, exposing a surface of the semiconductor layer at a bottom portion of the through-hole by removing the insulating film exposed at the bottom portion of the through-hole, and forming a second electrode on the surface of the exposed semiconductor layer.

Embodiments will now be described with reference to the drawings. Similar components in the drawings are marked with like reference numerals.

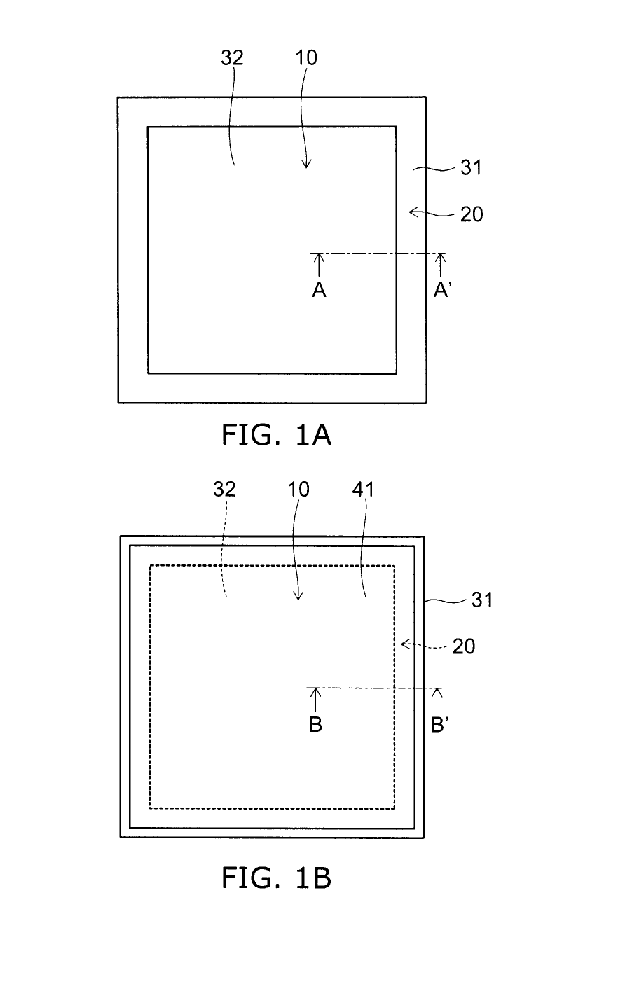

FIGS. 1A and 1B are schematic plan views of a semiconductor device of an embodiment. FIG. 1A illustrates the state prior to forming a second electrode 41 illustrated in FIG. 1B.

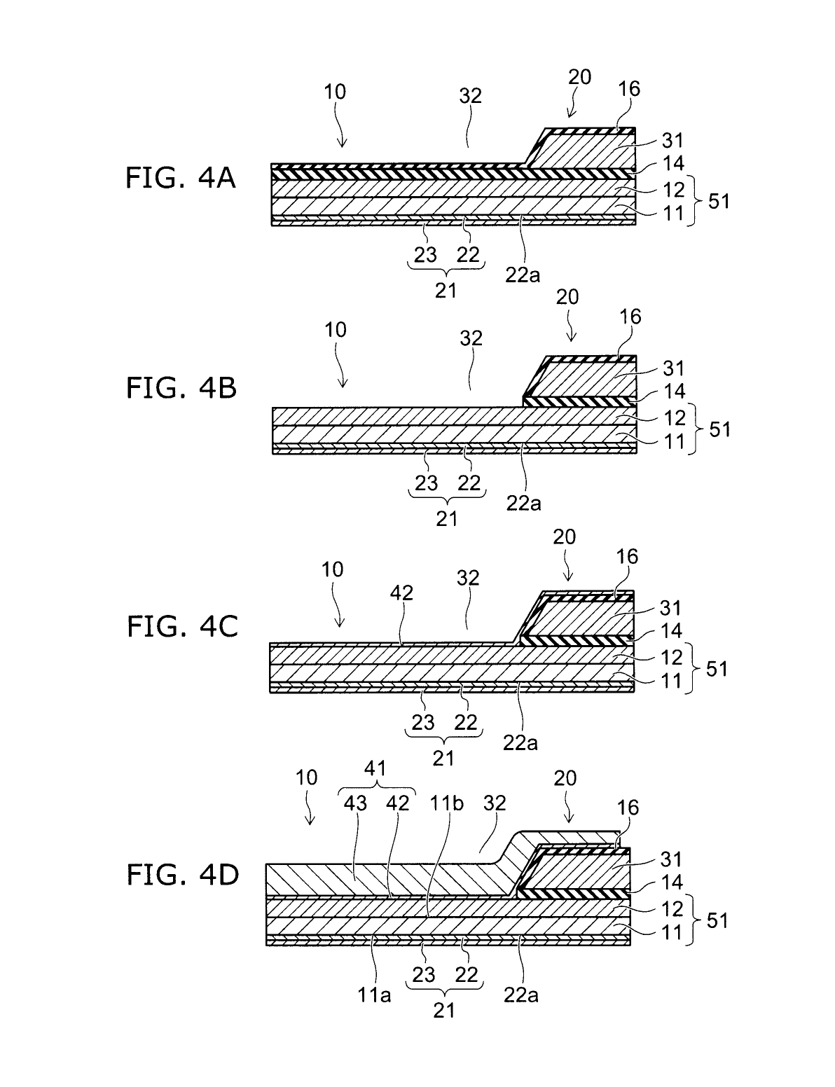

FIG. 4D is a schematic cross-sectional view of the semiconductor device of the embodiment and corresponds to cross section B-B′ of FIG. 1B.

The semiconductor device of the embodiment is a vertical device in which the main current flows in a vertical direction that connects a first electrode 21 provided on a first surface 11a side of a silicon carbide (SIC) substrate 11 to the second electrode 41 provided on a second surface 11b side opposite to the first surface 11a. In the following embodiment, a Schottky Barrier Diode (SBD) is described as an example of such a vertical device.

As illustrated in FIG. 4D, the semiconductor device of the embodiment has a structure in which a silicon carbide layer 12 is provided as a semiconductor layer on the second surface 11b of the silicon carbide substrate 11. The silicon carbide layer 12 is, for example, a layer that is epitaxially grown on the second surface 11b of the silicon carbide substrate 11.

The silicon carbide layer 12 and the silicon carbide substrate 11 are conductive and include an impurity of the same conductivity type. For example, both the silicon carbide layer 12 and the silicon carbide substrate 11 are an n type.

Alternatively, the silicon carbide layer 12 and the silicon carbide substrate 11 may be a p type.

In the embodiment herein, the regions of the stacked body of the silicon carbide substrate 11 and the silicon carbide layer 12 that spread in the surface direction are divided into an element region 10 and a peripheral region 20.

The element region 10 includes at least a region where the main current flows in the vertical direction. The peripheral region 20 is a region that is further on the edge portion side than is the element region 10. Herein, the edge portion refers to the surface-direction edge-most portion of the semiconductor device singulated from the wafer.

As illustrated in FIGS. 1A and 1B, the planar configuration of the semiconductor device of the embodiment is, for example, a quadrilateral configuration. The peripheral region 20 is formed on the edge side of the quadrilateral; and the element region 10 is formed inside the peripheral region 20. The peripheral region 20 continuously surrounds the periphery of the element region 10 outside the element region 10.

An insulating film (a first insulating film) 14 is provided on the surface of the peripheral region 20 of the silicon carbide layer 12.

The insulating film 14 includes, for example, silicon oxide and is an inorganic insulating film such as a silicon oxide film, a silicon oxynitride film, etc. Alternatively, a silicon nitride film may be provided as the insulating film 14. In the embodiment, a silicon oxide film is provided as the insulating film 14.

A silicon substrate 31 is provided as a reinforcing substrate on the insulating film 14. The insulating film 14 and the silicon substrate 31 that is provided on the insulating film 14 continuously surround the element region 10 when viewed in plan as illustrated in FIG. 1A.

The silicon substrate 31 has a structure in which a through-hole 32 is provided on the inner side of the silicon substrate 31 on the element region 10 side. As illustrated in FIG. 4B described below, the through-hole 32 reaches the surface of the silicon carbide layer 12 of the element region 10.

The peripheral region 20 is reinforced with the silicon substrate 31. The silicon substrate 31 has the same thickness as the silicon carbide substrate 11 or is thicker than the silicon carbide substrate 11. Alternatively, there are cases where the silicon substrate 31 is thinner than the silicon carbide substrate 11.

As illustrated in FIG. 4D, the first electrode 21 is provided on the first surface 11a of the silicon carbide substrate 11. The first electrode 21 has ohmic contact with the first surface 11a of the silicon carbide substrate 11. The first electrode 21 is provided on the entire surface of the first surface 11a.

The first electrode 21 includes a metal film 22 and a metal film 23. The metal film 22 is, for example, a nickel film. The metal film 23 includes, for example, a titanium film, a nickel film, and a gold film provided in order from the metal film 22 side.

The side of the metal film 22 on the side of the interface with the first surface 11a is metal-silicided. For example, a metal film 22 that is a nickel film includes a nickel silicide film 22a provided on the side of the interface with the first surface 11a. The materials and the configuration of the first electrode 21 described above are examples; and other materials and configurations may be used.

The second electrode 41 is provided inside the through-hole 32 that is made in the silicon substrate 31. For example, the second electrode 41 includes a metal film 42 that has a Schottky junction with the surface of the silicon carbide layer 12 of the element region 10 and a copper pad 43 provided on the metal film 42.

As described below, the metal film 42 functions as a seed layer when forming the copper pad 43 by plating. The metal film 42 includes, for example, a titanium film and a copper film provided in order from the surface side of the silicon carbide layer 12. The materials and the configuration of the second electrode 41 are examples; and other materials and configurations may be used.

The copper pad 43 is thicker than the metal film 42 and is filled into the through-hole 32. The side surface of the silicon substrate 31 on the through-hole 32 side and the upper surface of the silicon substrate 31 are covered with an insulating film (a second insulating film) 16. The insulating film 16 is, for example, a silicon oxide film.

The metal film 42 is provided also on the insulating film 16 along the side surface and the upper surface of the silicon substrate 31. The copper pad 43 also is provided on the side surface and the upper surface of the silicon substrate 31. There are cases where the copper pad 43 is thicker than the silicon substrate 31; and there are cases where the copper pad 43 is thinner than the silicon substrate 31.

In the semiconductor device of the embodiment described above, in the case of a forward bias in which a relatively low potential is applied to the first electrode 21 and a relatively high potential is applied to the second electrode 41, a forward-direction current flows between the first electrode 21 and the second electrode 41 through the silicon carbide layer 12 and the silicon carbide substrate 11 of the element region 10.

In the case of a reverse bias in which a relatively high potential is applied to the first electrode 21 and a relatively low potential is applied to the second electrode 41, a depletion layer spreads through the silicon carbide layer 12 of the peripheral region 20; and a high breakdown voltage is obtained.

The insulating film 16 is provided between the silicon substrate 31 and the second electrode 41 which includes the metal film 42 and the copper pad 43 to insulate the second electrode 41 from the silicon substrate 31. Accordingly, current does not flow between the second electrode 41 and the silicon substrate 31.

Silicon carbide has a higher insulation breakdown voltage than silicon; and the semiconductor device of the embodiment in which the silicon carbide layer 12 is used as a drift layer or base layer is suited to high-power high-speed switching applications. Further, silicon carbide has higher thermal stability than silicon; and the semiconductor device of the embodiment can operate at high temperatures.

The resistance is reduced by reducing the thickness of the silicon carbide substrate 11 while supplementing the insufficient strength due to the silicon carbide substrate 11 being thinner by the silicon substrate 31 being provided in the peripheral region 20.

The surface of the silicon carbide layer 12 of the element region 10 can be connected to the second electrode 41 through the through-hole 32. The silicon substrate 31 is continuously provided on the peripheral region 20 so as to surround the through-hole 32. Therefore, the stress can be balanced in the direction along the edge portion of the semiconductor device when viewed in plan as in FIGS. 1A and 1B; and the strength does not become insufficient locally.

The copper pad 43 is filled into the through-hole 32 of the silicon substrate 31. Copper has lower electrical resistivity than, for example, aluminum; and the copper pad 43 improves the diffusability of the current in the surface direction. The resistance can be reduced even further by reducing the thickness of the silicon carbide substrate 11 while also providing the copper pad 43 on the front surface electrode side. As described below, a thick copper pad 43 can be formed easily in a short period of time by plating.

Copper has higher thermal stability and heat dissipation than, for example, aluminum and does not hinder a silicon carbide device having excellent high-temperature characteristics from being used at high temperatures.

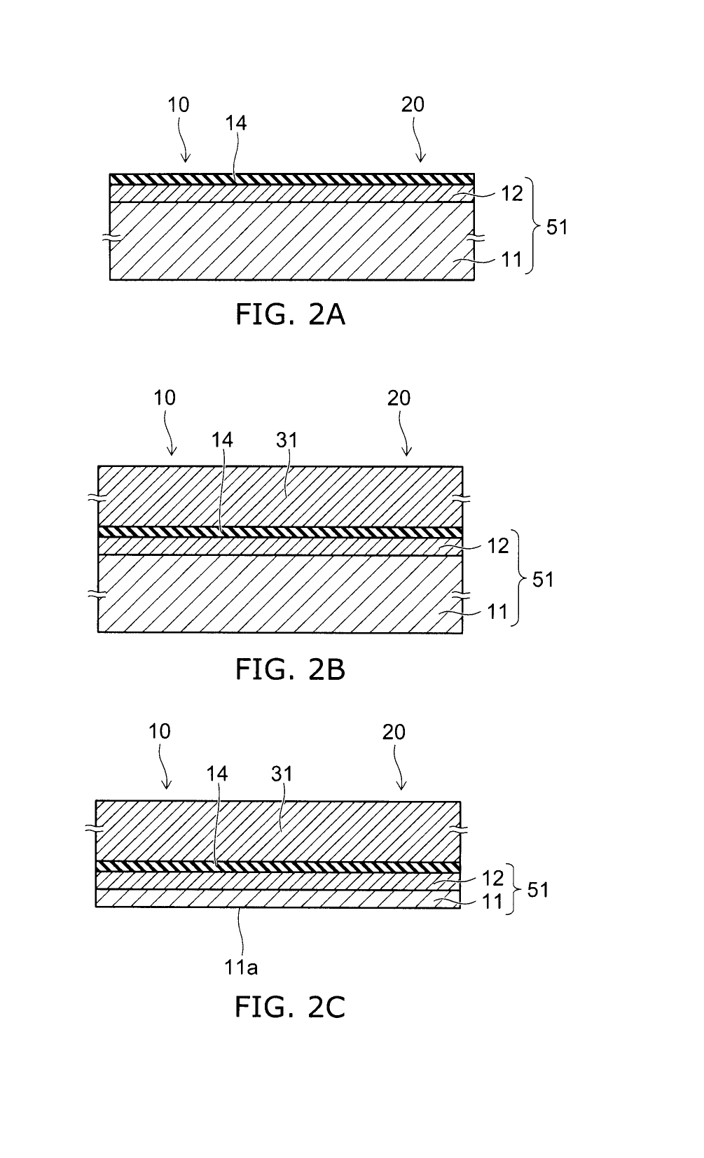

A method for manufacturing the semiconductor device of the embodiment will now be described with reference to FIG. 2A to FIG. 5C and FIG. 6.

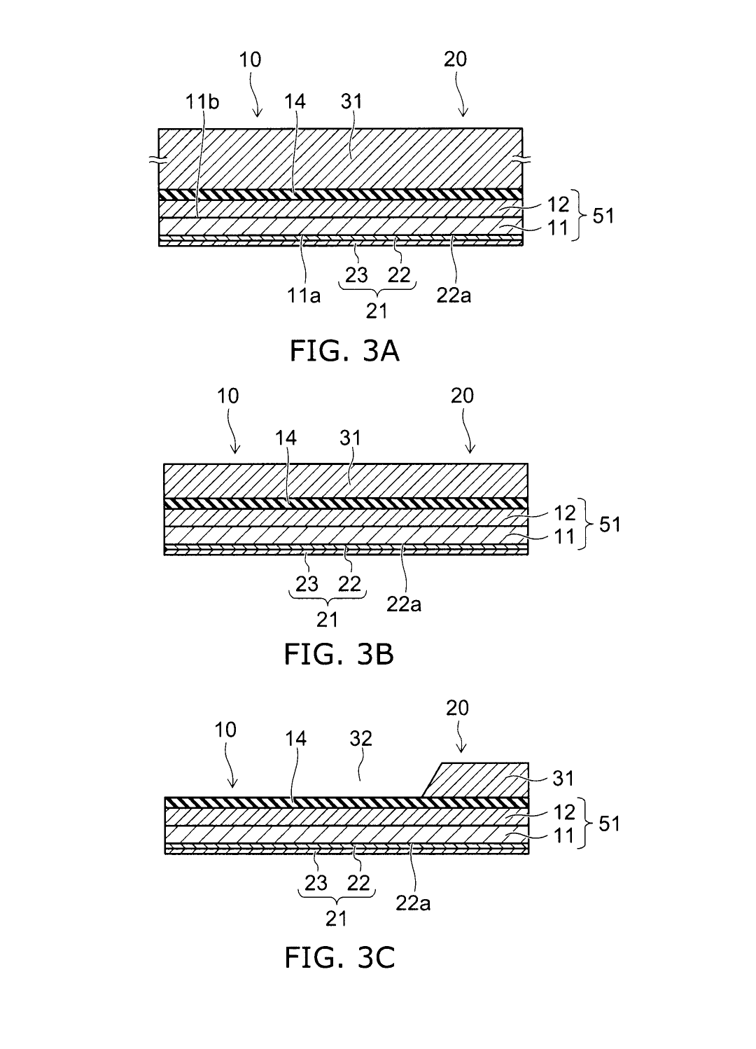

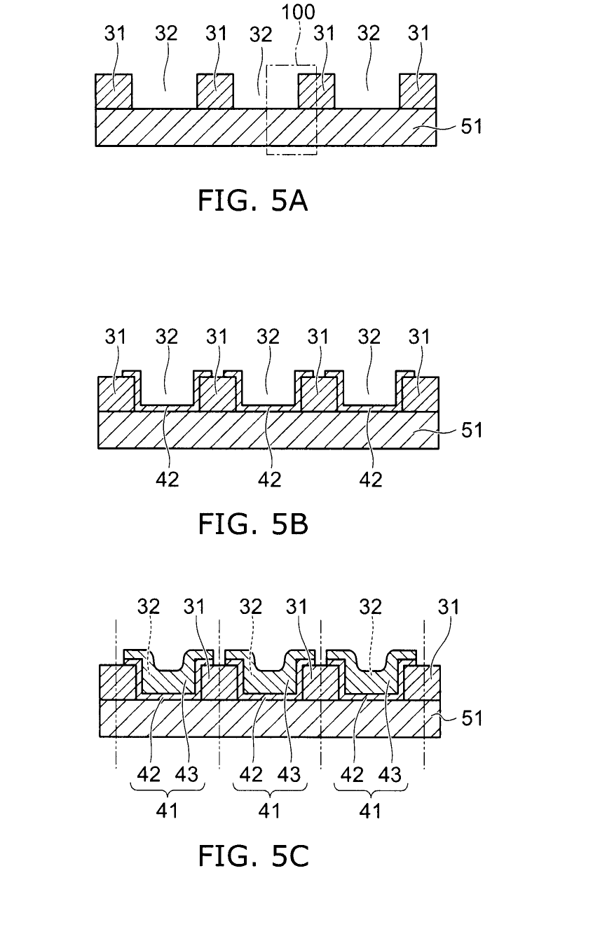

FIG. 5A to FIG. 5C illustrate a partial cross section of a region of the wafer that is larger than that of FIG. 2A to FIG. 4D. FIG. 3C is an enlarged cross-sectional view of a portion 100 surrounded with the single dot-dash line in FIG. 5A.

In FIG. 5A to FIG. 5C, not all of the components illustrated in FIG. 2A to FIG. 4D are illustrated; and only the main components are illustrated.

FIG. 2A illustrates a first wafer 51 in which the silicon carbide layer 12 is formed on the second surface 11b of the silicon carbide substrate 11. The silicon carbide layer 12 is formed on the second surface 11b of the silicon carbide substrate 11 by, for example, epitaxial growth.

Then, the insulating film 14 is formed on the surface of the silicon carbide layer 12. In the embodiment, for example, a silicon oxide film is formed as the insulating film 14. The insulating film 14 is formed over the entire surface of the element region 10 and the peripheral region 20.

The upper surface of the insulating film 14 is planarized by, for example, Chemical Mechanical Polishing (CMP). The film thickness of the insulating film 14 is, for example, about 1 μm.

Then, as illustrated in FIG. 2B, the silicon substrate 31 is bonded as a reinforcing substrate to the upper surface of the insulating film 14.

First, the upper surface of the insulating film 14 is activated by plasma processing. Subsequently, the silicon substrate 31 is attached to the insulating film 14 at room temperature in ambient air. Subsequently, for example, the silicon substrate 31 is bonded to the insulating film 14 by annealing at 200 to 400° C. Thereby, the first wafer 51, which includes the silicon carbide substrate 11 and the silicon carbide layer 12, is bonded to a second wafer made of the silicon substrate 31 with the insulating film 14 interposed.

Then, as illustrated in FIG. 2C, the first surface 11a of the silicon carbide substrate 11 is polished in the state of the first wafer 51 being supported by the silicon substrate 31. After the polishing, for example, the first surface 11a is planarized by CMP. Thereby, the thickness of the silicon carbide substrate 11 is reduced to, for example, not more than 100 μm.

Continuing as illustrated in FIG. 3A, the first electrode 21 is formed on the first surface 11a.

To form the first electrode 21, the metal film 22 is formed on the first surface 11a and the metal film 23 is formed on the metal film 22. For example, the metal film 22 is a nickel film; and the metal film 23 includes a titanium film, a nickel film, and a gold film formed in order from the metal film 22 side.

The nickel (Ni) of the metal film (the nickel film) 22 is caused to react with the silicon (Si) included in the silicon carbide substrate 11 by, for example, heat treatment at about 1000° C. Thereby, a nickel silicide film is formed as the metal silicide film 22a at the interface between the metal film (the nickel film) 22 and the first surface 11a. The first electrode 21 has ohmic contact to the silicon carbide substrate 11 via the metal silicide film 22a. Note that the temperature of the heat treatment is not limited to the about 1000° C., but appropriately set in accordance with the materials used and conditions of the pre-process and the post-process.

The formation of the metal silicide film 22a for the silicon carbide substrate 11 for which it is necessary to break the bond between silicon (Si) and carbon (C) requires a temperature (for example, about 1000° C.) that is higher than that of the formation of a metal silicide film on a silicon substrate. However, the resins and the metals generally used as materials to perform bonding between wafers do not have thermal stability with respect to temperatures of about 1000° C.

Therefore, in the embodiment, the insulating film 14 is used as a film to perform the bonding between the silicon substrate 31 and the silicon carbide substrate 11. The insulating film 14 which is an inorganic film such as a silicon oxide film, a silicon oxynitride film, a silicon nitride film, etc., has thermal stability with respect to temperatures of about 1000° C. In particular, a silicon oxide film and a silicon oxynitride film that include silicon oxide obtain a high bonding strength with the silicon substrate 31.

By using the insulating film 14 as the bonding layer, the temperature of the heat treatment recited above can be withstood to obtain ohmic contact between the silicon carbide substrate 11 and the first electrode 21; and after the heat treatment recited above, the thinner silicon carbide substrate 11 can be stably supported by the silicon substrate 31 which is thicker than the silicon carbide substrate 11.

A material that does not have thermal stability with respect to temperatures of about 1000° C. is not provided on the second surface 11b of the silicon carbide substrate 11 when performing the heat treatment to cause the metal silicide reaction recited above at the first surface 11a side of the silicon carbide substrate 11.

After forming the first electrode 21 as illustrated in FIG. 3B, the surface on the side of the silicon substrate 31 opposite to the insulating film 14 is polished and then planarized by CMP. The silicon substrate 31 is thinned to, for example, about 100 μm.

It is desirable for the silicon substrate 31 not to be thinner than the silicon carbide substrate 11 to stably support the silicon carbide substrate 11 which is made thinner in the previous process.

Then, as illustrated in FIG. 3C, the through-hole 32 is made in the silicon substrate 31. FIG. 3C corresponds to cross section A-A′ of FIG. 1A which illustrates the plane of one device. FIG. 3C corresponds to an enlarged cross section of the portion 100 surrounded with the single dot-dash line 100 in FIG. 5A which illustrates the wafer state in which multiple devices are formed.

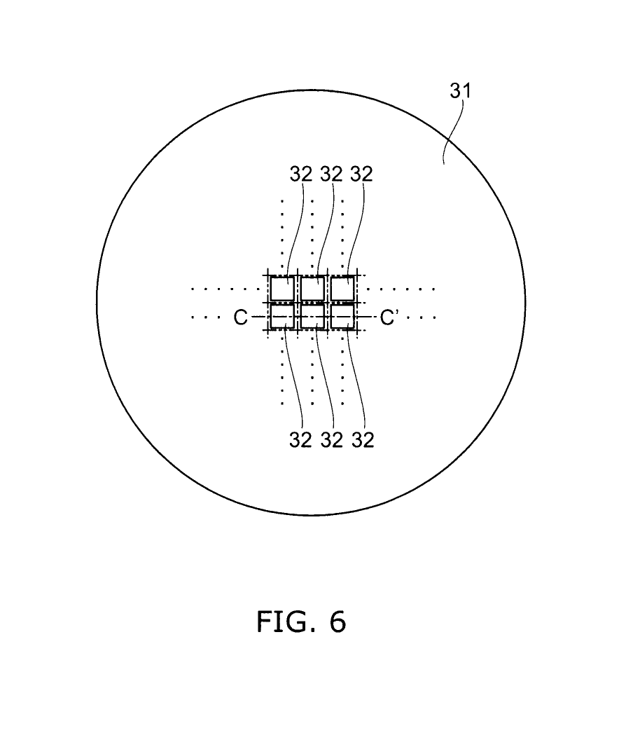

FIG. 6 is a plan view of the silicon substrate (the second wafer) 31 corresponding to the processes of FIG. 3C and FIG. 5A.

FIG. 5A is a cross-sectional view of, for example, a region including three through-holes 32 of FIG. 6 and corresponds to the enlarged cross section C-C′ of FIG. 6.

A not-illustrated resist film is formed on the upper surface of the silicon substrate 31 in the state of FIG. 3B. This resist film is patterned by exposing and developing. Then, the through-hole 32 is made by selectively etching the silicon substrate 31 as illustrated in FIG. 3C using the patterned resist film as a mask.

During this etching, the insulating film 14 which is a different type of material than the silicon substrate 31 functions as an etching stopper. In other words, the insulating film 14 is exposed at the bottom portion of the through-hole 32 that is made by the silicon substrate 31 being selectively removed.

As illustrated in FIG. 5A and FIG. 6, multiple through-holes 32 are formed in the silicon substrate 31. For example, one through-hole 32 is formed per chip. The silicon substrate 31 remains in a portion of the peripheral region 20; and the element region 10 is positioned under the through-hole 32.

After making the through-hole 32 as illustrated in FIG. 4A, for example, a silicon oxide film is formed as the insulating film (the second insulating film) 16 on the bottom portion and the side wall of the through-hole 32 and on the upper surface of the silicon substrate 31. Subsequently, the insulating film 16 of the bottom portion of the through-hole 32 and the insulating film 14 under the insulating film 16 are removed by being selectively etched.

Thereby, as illustrated in FIG. 4B, the surface of the silicon carbide layer 12 of the element region 10 is exposed at the bottom portion of the through-hole 32. The insulating film 16 formed on the side surface of the silicon substrate 31 on the through-hole 32 side and the insulating film 16 formed on the upper surface of the silicon substrate 31 remain by being covered with a not-illustrated mask during the etching recited above.

Then, as illustrated in FIG. 4C and FIG. 5B, the metal film 42 that functions as a seed layer of the second electrode 41 is formed on the surface of the silicon carbide layer 12 that is exposed at the bottom portion of the through-hole 32. The metal film 42 is formed also to cover the insulating film 16 remaining on the side surface and the upper surface of the silicon substrate 31.

The process of forming the second electrode 41 includes, for example, a process of forming the metal film 42 by sputtering and a process of forming the copper pad 43 by plating.

First, as illustrated in FIG. 4C and FIG. 5B, the metal film 42 is formed on the bottom portion and the side wall of the through-hole 32 and on the upper surface of the silicon substrate 31. The metal film 42 includes, for example, a titanium film and a copper film formed in order from the lower layer side. The metal film 42 has a Schottky junction with the surface of the silicon carbide layer 12 which is a semiconductor layer.

Or, the second electrode 41 may have ohmic contact with a portion of the silicon carbide layer 12. The ohmic contact is formed using a metal silicide film, e.g., a Ni silicide film. In such a case, the metal film 42 is formed on the metal silicide film.

The metal film 42 functions as a seed layer of plating; and the copper pad 43 is formed by plating using the metal film 42 as a current path.

As illustrated in FIG. 4D and FIG. 5C, the copper pad 43 is filled into the through-hole 32 to conform to the inner wall of the through-hole 32. The copper pad 43 extends along the side wall of the through-hole 32 onto the upper surface of the silicon substrate 31 to cover the stepped portion between the bottom portion of the through-hole 32 and the upper surface of the silicon substrate 31.

The first electrode 21 may be formed after the second electrode 41 is formed.

The processes described above are performed in the wafer state that includes multiple chips. Then, the wafer is subdivided into the multiple chips by dicing at the positions illustrated by the double dot-dash lines in FIG. 5C and FIG. 6.

The dicing is performed at the portion where the silicon substrate 31 remains. The width of the silicon substrate 31 is larger than the dicing width; and a portion of the silicon substrate 31 remains on the terminal side of the singulated semiconductor device.

The first electrode 21 is mounted on an interconnect substrate using, for example, solder and the like. The second electrode 41 is connected to the interconnect substrate using, for example, wires. Alternatively, the second electrode 41 may be bonded to the interconnect substrate using solder and the like.

According to the embodiment, the silicon carbide substrate 11 can be made thinner without the occurrence of cracks and breakage because the silicon carbide substrate 11, which is more brittle than silicon, is formed thinner while being reinforced by the silicon substrate 31.

The silicon substrate 31 is bonded to the first wafer 51 that includes the silicon carbide substrate 11 with the insulating film 14 interposed. Therefore, it is possible to perform high-temperature heat treatment to form the metal silicide film of the first electrode 21 at the first surface 11a of the silicon carbide substrate 11 after the polishing while using the silicon substrate 31 to maintain the support of the first wafer 51.

The depth of the through-hole 32 can be reduced by reducing the thickness of the silicon substrate 31 in the process of FIG. 3B prior to making the through-hole 32. As a result, it is possible to reduce the thickness of the copper pad 43 provided inside the through-hole 32. By reducing the thickness of the copper pad 43, warp due to the residual stress during the formation by plating can be suppressed.

By using the silicon substrate 31 as the reinforcing substrate, it is possible to selectively make the through-hole 32 easily with general exposing, developing, and etching processes applied to silicon wafers.

Or, the reinforcing substrate is not limited to a silicon substrate; and a glass substrate and the like may be used. Because a glass substrate is insulative, it is unnecessary for an insulating film to cover the side surface of the glass substrate on the through-hole 32 side and the upper surface of the glass substrate prior to forming the second electrode 41.

The embodiments described above are not limited to Schottky Barrier Diodes (SBDs) and are applicable also to other vertical devices such as p-intrinsic-n (PIN) diodes, Metal-Oxide-Semiconductor Field Effect Transistors (MOSFETs), Insulated Gate Bipolar Transistors (IGBTs), etc.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a silicon carbide substrate having a first surface and a second surface on a side opposite to the first surface;
a semiconductor layer having an element region and a peripheral region provided on the second surface of the silicon carbide substrate, the peripheral region being further on an edge portion side than is the element region;
an insulating film provided on a surface of the peripheral region of the semiconductor layer;
a reinforcing substrate provided on the insulating film in the peripheral region;
a first electrode provided in contact with the first surface of the silicon carbide substrate; and
a second electrode provided in contact with a surface of the element region.

2. The device according to claim 1, wherein the reinforcing substrate is a silicon substrate.

3. The device according to claim 1, wherein the semiconductor layer is a silicon carbide layer.

4. The device according to claim 1, wherein the reinforcing substrate continuously surrounds a periphery of the element region when viewed in plan.

5. The device according to claim 1, wherein the first electrode includes a metal silicide film provided at an interface between the first electrode and the silicon carbide substrate.

6. The device according to claim 1, wherein the second electrode includes copper.

7. The device according to claim 1, wherein the second electrode includes:
a metal film provided in contact with the surface of the element region; and
a copper pad provided on the metal film, the copper pad being thicker than the metal film.

8. The device according to claim 1, wherein the insulating film includes silicon oxide.

9. The device according to claim 1, wherein the peripheral region continuously surrounds a periphery of the element region.

10. A method for manufacturing a semiconductor device, comprising:
bonding a reinforcing substrate to a semiconductor layer with an insulating film interposed, the semiconductor layer being provided on a second surface of a silicon carbide substrate, the silicon carbide substrate having a first surface and the second surface on a side opposite to the first surface;
polishing the first surface of the silicon carbide substrate in a state of being supported by the reinforcing substrate;
forming a first electrode on the polished first surface;
making a through-hole in the reinforcing substrate to reach the insulating film;
exposing a surface of the semiconductor layer at a bottom portion of the through-hole by removing the insulating film exposed at the bottom portion of the through-hole; and
forming a second electrode on the surface of the exposed semiconductor layer.

11. The method according to claim 10, wherein a silicon carbide layer is epitaxially grown as the semiconductor layer on the second surface of the silicon carbide substrate.

12. The method according to claim 10, wherein the insulating film is planarized after being formed on the semiconductor layer, and the reinforcing substrate is bonded to a flat surface of the insulating film.

13. The method according to claim 12, wherein the bonding the reinforcing substrate on the flat surface of the insulating film includes:
attaching the reinforcing substrate to the flat surface after activating the flat surface by plasma processing; and
annealing after the attaching the reinforcing substrate to the flat surface.

14. The method according to claim 10, wherein a silicon substrate is bonded as the reinforcing substrate to the insulating film after the insulating film is formed on the surface of the semiconductor layer, the insulating film including a silicon oxide.

15. The method according to claim 10, wherein the through-hole is made by selective etching of the reinforcing substrate.

16. The method according to claim 10, wherein the forming the first electrode includes:
forming a metal film on the first surface of the silicon carbide substrate; and
forming a metal silicide film by heat treatment to cause the metal film to react with silicon included in the silicon carbide substrate.

17. The method according to claim 10, further comprising polishing the reinforcing substrate after the forming the first electrode and prior to the making of the through-hole.

18. The method according to claim 10, wherein the forming the second electrode includes:
forming a seed layer on the bottom portion and a side wall of the through-hole; and
filling copper into the through-hole by plating using the seed layer as a current path.

19. The method according to claim 10, further comprising covering a side surface of the reinforcing substrate on the through-hole side and an upper surface of the reinforcing substrate with a second insulating film after the making the through-hole and prior to the forming the second electrode.

20. The method according to claim 19, wherein the second electrode is formed also on the second insulating film.
